(19) United States
(12) Patent Application Publication
(10) Pub. No.: US 2015/0380626 A1
(43) Pub. Date: Dec. 31, 2015

(54) Thermoelectric Generator Arrangement

(71) Applicants: Paul Sidney Alexander VAN LINGEN, Johannesburg (ZA); Allan Mark GOLDBERG, Sandton (ZA)

(72) Inventors: Paul Sidney Alexander Van Lingen, Johannesburg (ZA); Allan Mark Goldberg, Sandton (ZA)

(21) Appl. No.: 14/649,690

(22) PCT Filed: Dec. 4, 2013
(86) PCT No.: PCT/IB2013/060621

§ 371 Date: Jun. 4, 2015

(30) Foreign Application Priority Data
Dec. 4, 2012 (ZA) 2012/09148

(51) Int. Cl. H01L 35/30; F23D 3/18; H01L 35/32

(52) U.S. Cl. CPC H01L 35/30; H01L 35/32; F23D 3/18

(57) ABSTRACT

Disclosed is a thermoelectric generator arrangement using a standard burner wick guide, for example, a kerosene lamp, as a heat source and burner used with the thermoelectric generator arrangement. The burner includes an inner tube having a circular inlet opening, a rectangular opening, and continuous sidewalls extending therebetween.

### BACKGROUND TO THE INVENTION

THIS invention relates to a thermoelectric generator arrangement and more particularly but not exclusively, to a thermoelectric generator arrangement using a standard burner wick guide, for example a kerosene lamp, as a heat source. This invention furthermore relates to a burner used with the thermoelectric generator arrangement, as well as a housing assembly for housing a fan, heat exchangers and thermoelectric module of the thermoelectric generator arrangement.

A large part of the global population does not have regular or reliable access to electricity. This constitutes a major problem, as electricity is a prerequisite for an acceptable quality of life. A further modern necessity is the use of a cellular phone or a tablet computer to facilitate communication, education and other day to day activities. It follows that the need to be able to charge these devices is of utmost importance.

Since the World Bank started Lighting Africa.org in 2007 there has been an attempt at providing “green” systems to the underprivileged, but progress has been slow and the proposed solutions inefficient. The major reason for this is that the approach has been to provide solar power, which appears to be able to provide electricity for the most needs but falls short due to the number of hours of sunlight required per day to charge the system's batteries, battery degradation, high initial cost and the enormous problem of theft if left unattended.

Thermoelectric generators (also called thermo generators) are devices which convert heat (and in particular temperature differences) directly into electrical energy, using a phenomenon called the “Seebeck effect” (or “thermoelectric effect”). The typical efficiency of these devices is around 5-10%. Older Seebeck-based devices used bimetallic junctions and were bulky, while more recent devices use bismuth telluride (Bi₂Te₃) or lead telluride (PbTe) semiconductor p-n junctions and can have thicknesses in the millimeter range. These are solid state devices and unlike dynamos have no moving parts, with the occasional exception of a fan. In this specification the thermoelectric generating device will be referred to as a TEG module.

Thermoelectric energy systems are known, but are not optimized for rural use. Existing systems are also not very efficient, and are usually heated with a heat source which has not been custom designed for the particular application. For example, the thermoelectric generators are often placed on top of a heated plate of a stove. In addition, it has been found that the cooling of existing thermoelectric energy systems (and in particular the TEG module) is not optimally designed, resulting in a substantial loss in efficiency. This is often caused by the air (used to heat one side of the thermoelectric element and also air emanating from the burner) being drawn into the cooling air stream (used to cool the other side of the thermoelectric element) resulting in suboptimal cooling and therefore a low temperature differential across the TEG module. The efficiency of the TEG module is determined by the temperature differential across the module, and insufficient cooling of the cold side of the TEG module therefore has a significant impact on the efficiency of the thermoelectric generating system.

Various forms of lamps are ubiquitous in communities that do not have access to electricity. Common examples are paraffin and kerosene lamps. These lamps are at present exclusively used for lighting, and the waste heat generated thereby is not harvested. For these reasons, the burner wick guides of these lamps are also not optimally designed with flame recovery in mind (i.e. the ability of the flame to remain lit or to auto-ignite when inadvertently extinguished). In addition, the flow profile of the combusted air is not an important design criteria, and existing lamps are therefore not inherently suitable for the efficiently transfer of exhaust heat. It should however be noted that the invention is not limited to use with a lamp used for lighting, but that it can be used with any standard burner wick guide irrespective of whether the intention is to generate light or not.

It is accordingly an object of the invention to provide a thermoelectric generator arrangement that will, at least partially, alleviate the above disadvantages.

It is also an object of the invention to provide a thermoelectric generator arrangement utilising a customized burner, and preferably a burner that is securable to an existing lamp or wick guide and which maximizes the burning efficiency of the lamp or wick guide in order to utilise the combustion heat in the generation of electricity.

It is a further object of the invention to provide a thermoelectric generator including a customized housing assembly, and preferably a housing assembly that provides the structure, support and spring loading for heat exchangers, a fan and a TEG module of the thermoelectric generator.

It is a further object of the invention to provide a thermoelectric generator including a customized housing assembly that enhances the heat transfer efficiency of the generator and the cooling of the TEG module.

### SUMMARY OF THE INVENTION

According to the invention there is provided a thermoelectric generator arrangement including a lamp having a fuel burner, the fuel burner comprising an inner tubular structure having a first open end that is circular in cross-section and a second open end that is polygonal in cross section.

There is provided for the second open end to be rectangular in cross section.

The circumference of the first open end is preferably substantially the same as the circumference of the second open end.

There is provided for at least one of the sidewalls of the inner tube to be inwardly slanted from the first open end to the second open end.

There is also provided for air inlet apertures to be provided in the inner tubular structure.

A further feature provides for a flame spreader to be provided on top of the burner adjacent the second end.

In a preferred embodiment the flame spreader is in the form of a V-shaped flow guide, with the sharp end of the flow guide pointing toward the second open end of the burner.

There is also provided for the burner to include an outer tube, which is in the form of a cylindrical sleeve extending about the inner tube.

According to a further aspect of the invention there is provided a thermoelectric generator arrangement including
a housing for housing
   a lower heat exchanger,
   a TEG module on top of the lower heat exchanger, and
   an upper heat exchanger on top of the TEG module
the housing including a lower skirt section that extends about the periphery of the lower heat exchanger, and an upper skirt section that extends about the periphery of the upper heat exchanger in order to force air entering the heat exchangers to travel vertically into the heat exchanger prior to escaping from sides of the heat exchangers.

There is provided for each skirt sections to extend between 15% and 25% from an open inlet end of the heat exchanger along the height of the heat exchanger.

There is provided for the circumferential area of the heat exchanger not covered by the skirt to be approximately the same as the inlet area of the heat exchanger.

The skirt sections may be secured to one another way of a plurality of vertically extending arms.

A further feature of the invention provides for a separation element to be locatable between two heat exchangers of the thermoelectric generator arrangement, the separation element being in the form of a planar rectangular disc having an aperture configured and dimensioned for receiving the TEG module provided in the proximal zone of the rectangular disc.

Recesses, configured and dimensioned for receiving the vertically extending arms, may be formed in the sides of the separation element in order for the arms to retain the separation element in a fixed orientation.

According to a further aspect of the invention there is provided a thermoelectric generator arrangement including a housing for housing two heat exchangers, a fan and a TEG module, characterized in that the heat exchangers and TEG module are secured in the housing by way of a compression spring arrangement.

According to a further aspect of the invention there is provided a thermoelectric generator arrangement including a housing for housing two heat exchangers, a fan and a TEG module, characterized in that an upper part of the housing and a lower part of the housing are connected by way of a plurality of arms, the arms having small cross-sectional areas in order to reduce heat transfer therethrough.

According to a further aspect of the invention there is provided a thermoelectric generator arrangement including a separation element that is locatable between two heat exchangers of the thermoelectric generator arrangement, the separation element being configured to serve as a positioning guide for a TEG module, while also reducing heat transfer between the two heat exchangers.

### BRIEF DESCRIPTION OF THE DRAWINGS

A preferred embodiment of the invention is described by way of a non-limiting example, and with reference to the accompanying drawings in which:

FIG. 1 is a perspective view of part of a thermoelectric generator located on a standard burner wick guide, excluding the heat exchangers, fan and TEG module;

FIG. 2 is a cross-sectional side view of the thermoelectric generator of FIG. 1;

FIG. 3 is a perspective view of a burner for use with the thermoelectric generator;

FIG. 4 is a cross-sectional side view of the burner of FIG. 3;

FIG. 5 is an end view of the burner of FIG. 3;

FIG. 6 is a perspective view of a housing of the thermoelectric generator, excluding the TEG module or the upper and lower heat exchangers;

FIG. 7 is a perspective view of a separating element used in the thermoelectric generator;

FIG. 8 is an exploded perspective view of the thermoelectric generator including the heat exchangers, fan and TEG module, but excluding the lamp on which the generator is located;

FIG. 9 is a schematic representation of the air flow profile of one potential thermoelectric generator arrangement that does not include the skirt arrangement of the invention; and

FIG. 10 is a schematic representation of the air flow profile of the thermoelectric generator arrangement in accordance with a preferred embodiment of the invention.

### DETAILED DESCRIPTION OF INVENTION

Referring to the drawings, in which like numerals indicate like features, a non-limiting example of thermoelectric generator arrangement in accordance with the invention is generally indicated by reference numeral 10. The thermoelectric generator arrangement includes a standard burner wick guide 11 (for example in the form of a lamp), a burner arrangement 20, a TEG module housing 30, a TEG module 40 located inside the housing, a lower heat exchanger 50, upper heat exchanger 60 and fan 70. It should be noted that the terms heat sink and heat exchanger are used interchangeably.

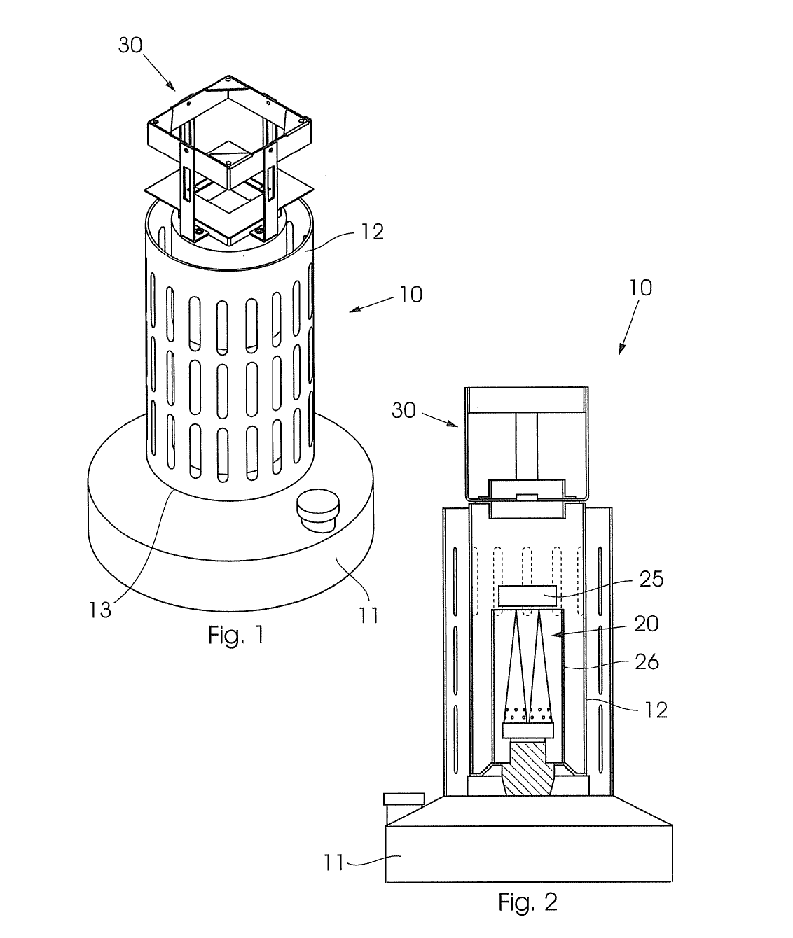

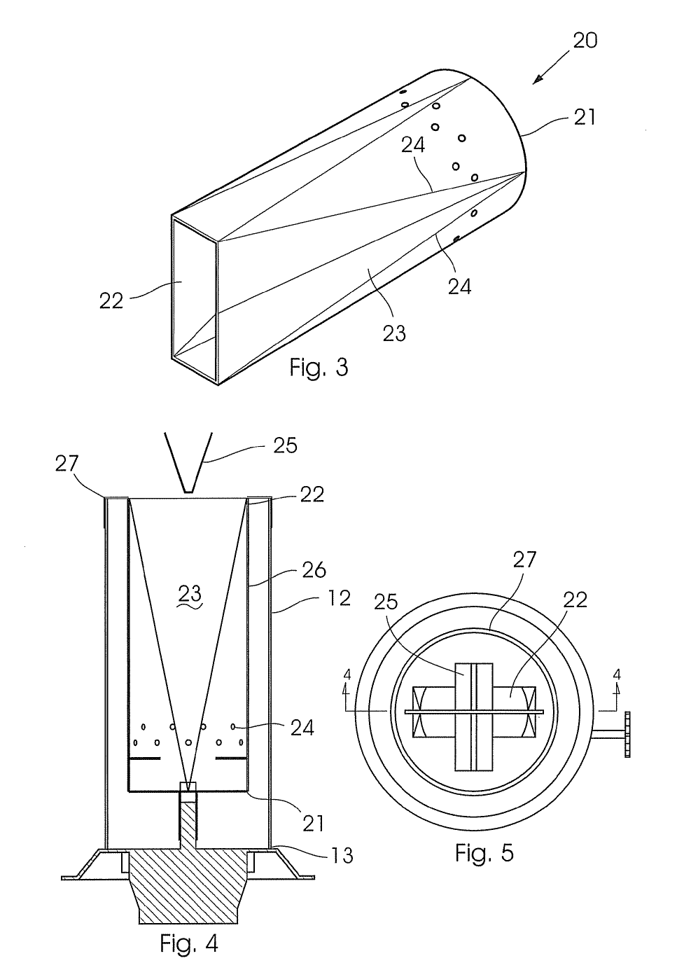

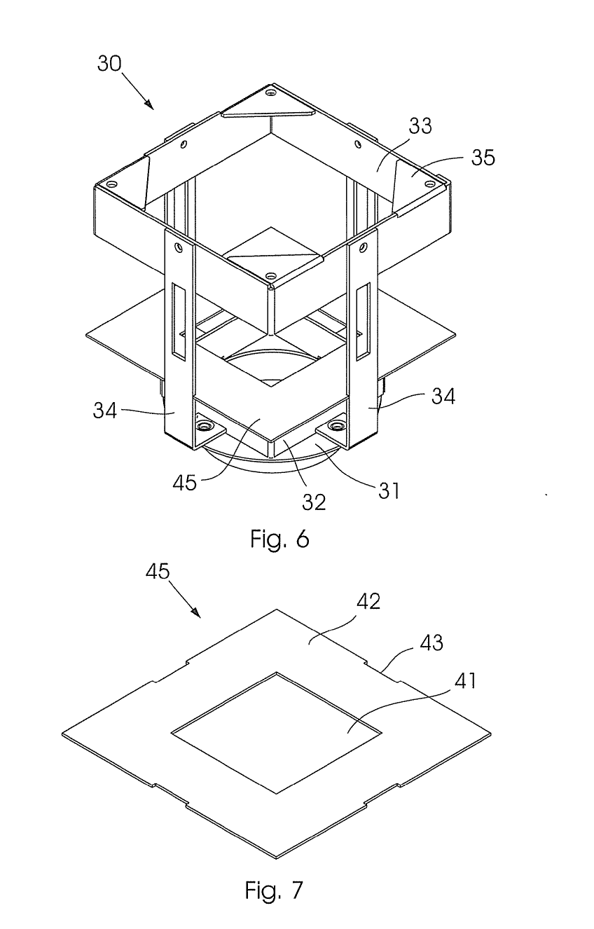

Referring now to FIGS. 1 to 5, the burner 20 consists of an inner tube 26 which initiates as a round base 21 and gradually progresses to a rectangular outlet 22 of the same circumference as the circular base. One end of the inner tube will therefore be circular in cross-section, and the other end will be rectangular with slanted sidewalls extending therebetween. The base 21 of this tube 26 is connected to a cap/adapter 13 which connects the tube to a standard burner wick guide. Perforations 24 are provided in the inner tube 26. The lower end (approximately 10 mm) of the inner tube 26 does not have any perforations, which prevents the wick from being damaged. Further perforations (not shown in the drawings) may be provided at intervals along the inner tube 26 up to the outlet. The slanted sidewalls of the inner tube 26 have a considerable effect on the relight characteristics of the burner. The inventors have found that a burner with vertical walls don't relight as efficiently as one with slanted walls, but at the same time a substantial reduction in outlet surface area (for example should a conical inner tube be used) is also not ideal. The use of a burner that starts off circular and ends in a rectangular profile results in the side surfaces of the burner to be inwardly slanted, even though the smaller area end surfaces may be vertical or even slightly outwardly slanting.

The burner 20 also includes an outer tube 28, which also terminates against the cap/adapter 13. The outer tube 28 extends along the entire length of the inner tube 26. The outer tube is closed at the top by an annular cap 27 that extends between the upper edge of the outer tube 28 and the inner tube 26, leaving the inner, rectangular opening of the inner tube 26 open. A flame spreader 25 is secured on top of the burner 20.

The burner 20 creates an environment where efficient combustion occurs, and which in addition has favorable relighting characteristics.

Heat transferred initially from the flame to the wick-guide increases the production of fuel vapor which in turn increases the temperature inside the perforated inner tube 26. This creates convection which is controlled by the inner tube 26 shape, the perforations 24 and the sealing of the outer tube 28. The temperature increases to a stable point where, in this environment, it enables blue flame combustion at the level of the first perforations 24. The stability of this burner is enhanced by the unusual and unexpected shape and dimensions of the design, and coupled with the efficiency, provides a stable heat source for the application. The burner in addition allows a 98% recovery (relighting) should the flame be disturbed by breeze or draft. A standard kerosene lamp burns approximately 50 ml/h at maximum burn (before sooting) and provides 80% of the heat required for thermoelectric generation. The new burner burns 35 ml/h providing 100% of the heat needed and at 50 ml/h can provide 150% of the required heat without sooting.

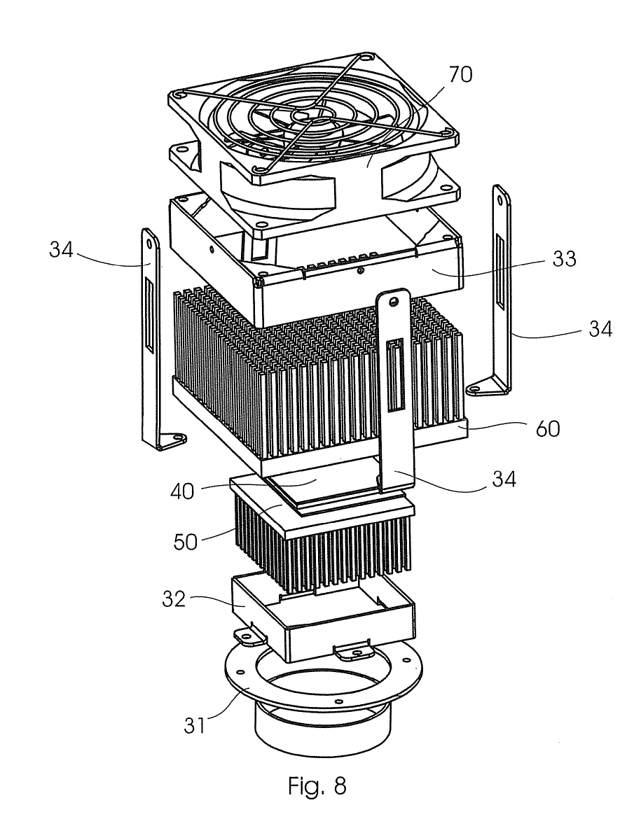

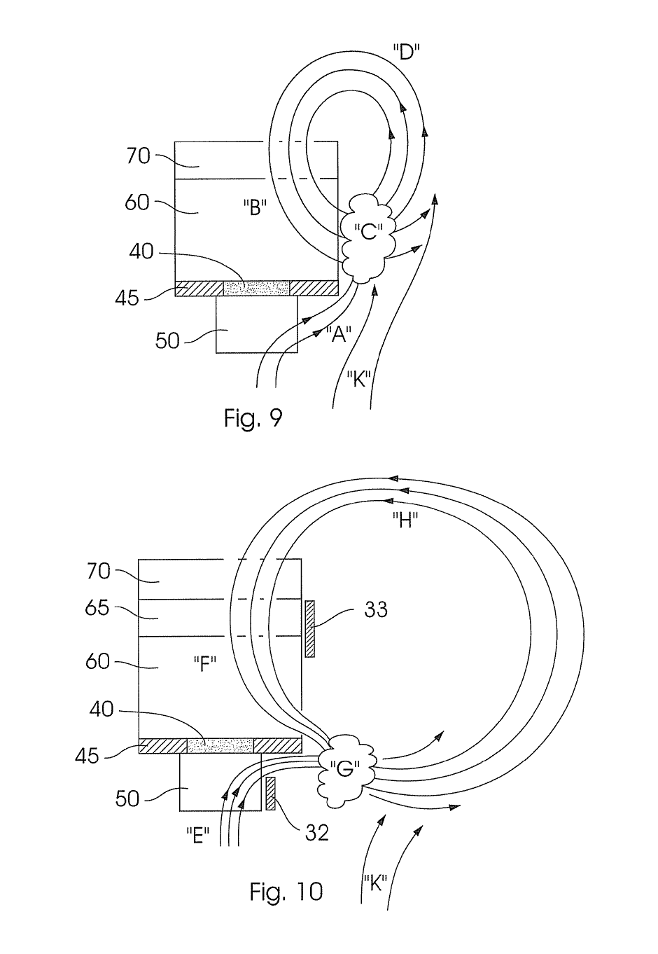

Referring now to FIGS. 6 to 8, the housing 30 of the TEG generator is securable to the upper end of the burner 20 by way of a base ring 31. The operatively smaller and lower heat exchanger 50 is located on top of the base ring 31, and is surrounded by a skirt 32 that keeps the heat sink 50 in position, but which also plays an important role in obtaining the required air flow profile, as is discussed in more detail below.

The TEG module 40 is located on top of the lower heat exchanger 50, and the upper heat exchanger 60 is located on top of the TEG module 40. In use, the lower heat exchanger 50 will transfer heat to the TEG module 40, whereas the upper heat exchanger 60 will remove heat from the TEG module. The upper heat exchanger 60 is located inside an upper heat exchanger skirt 33, and the cooling fan 70 is also secured to the upper heat exchanger skirt. The upper heat exchanger skirt 33 is connected to the base ring 31 by way of side straps 34, which are of minimum area in order to minimise conductive heat transfer via the side straps 34. In addition, the reduced area of the side straps 34 ensures that they do not interfere with the convective flow profiles through the two heat exchangers (50 and 60). The lower heat exchanger 50 is also surrounded by a skirt 32, which is secured to the base ring 31.

Both the heat exchangers (50 and 60) are in the form of 360 degree pin fin heat sinks, resulting in air entering the heat exchangers at an upper end thereof travelling axially along at least parts of the pins, and then being discharged radially outwardly away from the heat exchanger. The use of a pin fin heat exchanger is important, because the resultant discharge flow pattern it assists in diverting the flow of hot air from the burner around the full circumference of the heat exchanger, which is discussed in more detail below.

A unique hot side, cool side separation element 45 provides the positioning guide for the TEG module 40 and reduces heat transfer to the cold heat exchanger 60, which is essential in order to maintain an optimal temperature differential across the TEG module. The element 40 comprises a body 42 having a central aperture 41 for receiving the TEG module 40. Slots 43 are provided in the sides of the body for receiving the connecting arms or side straps 34.

Hot air enters the operatively lower hot heat exchanger 50 via the base ring adapter 31. The hot heat exchanger skirt 32 controls the convection rate and directs the path of the air through the heat exchanger. More particularly, the skirt 32 extends along the side of the heat exchanger 50 and therefore ensures that the maximum heat exchanger volume is exposed to the hot air. In addition, it also ensures that the outlet direction of the hot air is substantially radially outwardly, the importance of which will be discussed in more detail below.

The TEG module 40 placed between the heat sinks is localized by a separating element 45 in the form of an insulating fiber-board, which in turn is localized by the four straps 34 which also support the cold heat sink skirt 33, as well as the fan mount and compression spring support structure 35. The separating element 45 has two functions. The first is to locate the TEG module 40 and to prevent movement thereof, and the second is to create an insulating barrier between the two heat exchangers 50 and 60. Any heat transfer from the hot heat exchanger 50 to the cold heat exchanger 60 will have a significant impact on the efficiency of the system due to the reduction in the temperature differential across the system.

The cold heat exchanger skirt 33 controls the convection rate and directs the path of heat through the cold heat exchanger 60. More particularly, the skirt 33 extends from the upper surface or inlet of the heat exchanger along about 20% of the height of the heat exchanger 60 and ensures that the bulk of the heat exchanger is exposed to the cooling air. In addition, the skirt reduces the exit area of the heat exchanger compared to the situation where the skirt is omitted, and therefore ensures that the outlet velocity is not less than the inlet velocity. It should be noted that the skirt does not extend far enough to result in the outlet area of the heat sink being smaller than the inlet area. The skirt will therefore not have a flow restricting effect, but will result in the outlet and inlet areas being the same or similar. The skirt 33 furthermore protrudes above the upper surface of the heat exchanger 60, and defines an enclosed volume 65 between the upper end of the heat exchanger 60 and the lower end of the fan 70. This volume acts as a heat sink intake volume that assists in the equal distribution of cooling air across the inlet face of the heat exchanger 60. A high degree of axial flow relative to the pins is therefore achieved, which improves the efficiency of heat exchanged in the heat exchanger 60.

The situation where the skirts (32 and 33) are omitted is schematically illustrated in FIG. 10. Due to the lack of skirting the air flow will follow the path of least resistance, as is indicated by arrows A and B. The result of this is that the full heat exchange area is not utilized due to some of the heating (A) or cooling (B) air short circuiting the hot air heat exchanger 50 and cold air heat exchanger 60 respectively. This is not optimal, as it results in inefficient heat transfer which is particularly problematic in the thermoelectric generating application due to the requirement of a high temperature differential across the TEG module. In addition, the flow of air leaving the heat exchangers is not concentrated (indicated by the spacing between the flow lines) and the airflow out of both the heat exchangers is therefore at low velocity, resulting in low momentum. The airflow leaving the upper heat exchanger 60 (which is induced by forced convection using the fan 70) will have a downward directional component, but will have a relatively low velocity. Likewise, the airflow leaving the lower heat exchanger 50 (which is a result from natural convection) will have a relatively large upward directional component, and will also have a relatively low velocity. The two streams will meet in a mixing zone C, and will have limited effect on one another due to the low velocities. This will result in a large amount of the hot air A leaving the bottom heat exchanger 50 effectively moving along in an upward direction unperturbed, and this hot air will then (at least in part) be drawn into the upper heat exchanger 60, which is obviously not ideal from a cooling point of view. In addition, further hot air escaping the burner, denoted by arrows K, will rise adjacent the thermoelectric generator, and will further increase the inlet temperature of air entering the fan 70.

The effect of the addition of skirts 32 and 33 is schematically illustrated in FIG. 11. The air E flowing into and through the lower heat exchanger 50 and the air F forced into the upper heat exchanger 60 are forced to travel a longer distance through the heat exchangers. The first advantage of this arrangement is that a larger part of the heat transfer areas of the heat exchangers are utilized. A second advantage is that the flow of air leaving the heat exchangers are more concentrated, resulting in higher exit velocity flow profiles. The velocities of the two streams result in improved mixing of the hot and cold air when the two streams meet at a mixing zone G, and more importantly the combined stream continues to travel outwardly. The air will eventually be reintroduced into the fan 70 along flow path H, but the flow path is much longer which leaves more time for the air to cool down. The average inlet temperature of air being entering the fan will therefore be lower than in the case where the skirts are omitted. This combined exit stream also diverts the rising air K emanating from the burner.

The inventors have found that the air inlet temperature when no skirt is used is typically between 80 and 150 degrees above ambient due to the large amount of air emanating from the burner entering the cooling fan. However, the inlet temperature falls to a few degrees above the ambient temperature (2-7° C.) when the skirt is introduced. The introduction of the skirt is therefore a significant improvement over the prior art, and has a material impact on the performance of the thermoelectric generator.

The amount of electricity available from the above system is approximately 1.2 Amps at 5 Volts. This is sufficient energy to provide 150 Lumens of light (a standard lantern provides 8-10 Lumens) and in addition 500 ma of power @ 5V (USB) to charge a cell phone or tablet. This 500 ma of power can also be used to power additional led lights if not charging. This is achieved by using only 35 ml of kerosene per hour, thus resulting in the use of a total of 140 ml of fuel, for an evening

It will be appreciated that the above is only one embodiment of the invention and that there may be many variations without departing from the spirit and/or the scope of the invention.

1. A thermoelectric generator arrangement including a lamp having a fuel burner, the fuel burner comprising an inner tubular structure having a first open end that is circular in cross-section and a second open end that is polygonal in cross section.

2. The thermoelectric generator arrangement of claim 1, wherein the second open end is rectangular in cross section.

3. The thermoelectric generator arrangement of claim 1, wherein the circumference of the first open end is substantially the same as the circumference of the second open end.

4. The thermoelectric generator arrangement of claim 1, wherein at least one of the sidewalls of the inner tube is inwardly slanted from the first open end to the second open end.

5. The thermoelectric generator arrangement of claim 1, wherein air inlet apertures are provided in the inner tubular structure.

6. The thermoelectric generator arrangement of claim 1, wherein a flame spreader is provided on top of the burner adjacent the second end of the burner.

7. The thermoelectric generator arrangement of claim 6, wherein the flame spreader is in the form of a V-shaped flow guide, with the sharp end of the flow guide pointing toward the second open end of the burner.

8. The thermoelectric generator arrangement of claim 1, wherein the burner includes an outer tube, which is in the form of a cylindrical sleeve extending about the inner tube.

9. A thermoelectric generator arrangement including:
a housing for housing
a lower heat exchanger,
a TEG module on top of the lower heat exchanger, and
an upper heat exchanger on top of the TEG module,
with the housing including a lower skirt section that extends about the periphery of at least part of the lower heat exchanger, and an upper skirt section that extends about the periphery of at least part of the upper heat exchanger in order to reduce outlet areas of the heat exchangers.

10. The thermoelectric generator arrangement of claim 9, wherein each skirt section extends from an inlet end of the heat exchanger towards a base of the heat exchanger between 15 and 25% of the height of the corresponding heat exchanger.

11. The thermoelectric generator arrangement of claim 9, wherein the outlet area of the heat exchanger, as reduced by the skirt section, is substantially the same as the inlet area of the heat exchanger.

12. The thermoelectric generator arrangement of claim 10, wherein the skirt sections are secured to one another way of a plurality of vertically extending arms.

13. The thermoelectric generator arrangement of claim 9, wherein a separation element is locatable between the two heat exchangers of the thermoelectric generator arrangement, the separation element being in the form of a planar rectangular disc having an aperture configured and dimensioned for receiving the TEG module provided in the proximal zone of the rectangular disc.

14. The thermoelectric generator arrangement of claim 13, wherein recesses, configured and dimensioned for receiving the vertically extending arms, are formed in the sides of the separation element in order for the arms to retain the separation element in a fixed orientation.

15. The thermoelectric generator arrangement of claim 9, wherein the upper skirt section extends beyond an upper surface of the upper heat exchanger, and wherein the fan is spaced apart from the upper surface of the heat exchanger so as to define an enclosed volume between the upper heat exchanger and a fan of the thermoelectric generator arrangement.
